(19) United States
(12) Patent Application Publication
(10) Pub. No.: US 2018/0248336 A1
(43) Pub. Date: Aug. 30, 2018

(54) ASSEMBLY OF SEMICONDUCTOR AND HIGHLY THERMALLY CONDUCTIVE HEAT-DISSIPATING SUBSTRATES

(71) Applicant: LUXNET CORPORATION, Zhongli City (TW)

(72) Inventors: Hsing-Yen LIN, Zhongli City (TW); Pi-Cheng LAW, Zhongli City (TW); Po-Chao HUANG, Zhongli City (TW); Bo-Wei LIU, Zhongli City (TW); Ya-Hsin DENG, Zhongli City (TW); Hua-Hsin SU, Zhongli City (TW)

(21) Appl. No.: 15/863,662

(22) Filed: Jan. 5, 2018

(30) Foreign Application Priority Data
Feb. 24, 2017 (TW) 106202718

(51) Int. Cl. H01S 5/024; H01S 5/022

(52) U.S. Cl. CPC H01S 5/02469; H01S 5/02272; H01S 5/02476

(57) ABSTRACT

An assembly of semiconductor and highly thermally conductive heat-dissipating substrates includes a thermally conductive metal substrate, a supporting substrate, and a vertical heat-dissipating block. The thermally conductive metal substrate comprises a substrate body, a receiving groove in the substrate body, and a thin-layer portion at a bottom side of the receiving groove. The supporting substrate is provided in the receiving groove. The two vertically opposite sides of the supporting substrate respectively form a carrying surface for carrying a laser diode LD and a heat-dissipating surface in contact with the thin-layer portion at the bottom side of the receiving groove. The vertical heat-dissipating block is provided on a side of the thermally conductive metal substrate opposing to a side with the receiving groove.

### BACKGROUND OF THE INVENTION

### 1. Technical Field

The present invention relates to an assembly of semiconductor and heat-dissipating substrate, especially to an assembly of semiconductor and highly thermally conductive heat-dissipating substrate.

### 2. Description of Related Art

Recently, with the rapid development of technology, laser diodes (LDs) have been widely used in the optoelectronics industry. In particular, laser diodes are now in extensive use in the field of fiber-optic communications thanks to their short response time, high efficiency, and high output power.

As a high-power semiconductor device, however, a laser diode generates heat during operation. If the heat cannot be effectively dissipated, the junction temperature of the semiconductor will rise, thus lowering the operating efficiency of the semiconductor device, and the stability, optical emission efficiency, or even service life of the laser diode may be compromised as a result. Therefore, heat dissipation from laser diodes has long been a major issue.

Conventionally, metal blocks, which feature high thermal conductivity, are used as heat-dissipating substrates, but this kind of substrates are prone to expand when subjected to heat resulting from prolonged contact with a high-temperature heat source. If such a metal block deforms, the laser diode it carries, and consequently the optical path of the entire assembly, may be shifted such that optical coupling efficiency is lowered. To overcome the aforesaid problems, which arise mainly from poor thermal conduction, the inventor of the present invention believes that an assembly of semiconductor and highly thermally conductive heat-dissipating substrates is needed.

### BRIEF SUMMARY OF THE INVENTION

In view of the above, the present invention aims to address the thermal conduction issue of the conventional heat-dissipating substrates, lest they absorb a large amount of heat and thus generate a high temperature that lowers the operating efficiency of the semiconductor supported on the substrates.

To address the aforesaid issues of the conventional heat-dissipating substrate, the objective of the present invention is to provide an assembly of semiconductor and highly thermally conductive heat-dissipating substrates, including a thermally conductive metal substrate, a supporting substrate, and a vertical heat-dissipating block. The thermally conductive metal substrate comprises a substrate body, a receiving groove in the substrate body, and a thin-layer portion in a bottom side of the receiving groove. The supporting substrate is provided in the receiving groove, has a lower coefficient of thermal expansion than the thermally conductive metal substrate, and has two vertically opposite sides that respectively form a carrying surface for carrying a laser diode and a heat-dissipating surface in contact with the thin-layer portion at the bottom side of the receiving groove. The vertical heat-dissipating block is provided on a side of the thermally conductive metal substrate that faces away the receiving groove, and has a lower coefficient of thermal expansion than the thermally conductive metal substrate so as to absorb heat conducted downward from the thin-layer portion.

Further, a thickness of the thin-layer portion is not greater than half of that of the thermally conductive metal substrate.

Further, the receiving groove extends from one edge of the thermally conductive metal substrate to the opposite edge.

Further, the supporting substrate is made of aluminum nitride (AlN) materials.

Further, the thermally conductive metals substrate is made of copper (Cu) materials.

Further, the vertical heat-dissipating block is made of aluminum nitride (AlN) materials.

Further, a metal solder layer is provided between the supporting substrate and the laser diode so as to fix the laser diode to the supporting substrate.

Further, the metal solder layer is made of gold-tin alloy (AuSn) materials.

Another objective of the present invention is to provide an assembly of semiconductor and highly thermally conductive heat-dissipating substrates, including a thermally conductive metal substrate, a supporting substrate, and a vertical heat-dissipating block. The thermally conductive metal substrate comprises a substrate body, a first receiving groove in the substrate body, a second receiving groove on a side of the substrate body that faces away from the first receiving groove, and a thin-layer portion between the first receiving groove and the second receiving groove. The supporting substrate is provided in the first receiving groove, has a lower coefficient of thermal expansion than the thermally conductive metal substrate, and has two vertically opposite sides that respectively form a carrying surface for carrying a laser diode and a heat-dissipating surface in contact with the thin-layer portion at an bottom side of the first receiving groove. The vertical heat-dissipating block is provided in the second receiving groove, and has a lower coefficient of thermal expansion than the thermally conductive metal substrate so as to absorb heat conducted downward from the thin-layer portion.

Further, a thickness of the thin-layer portion is not greater than half of that of the thermally conductive metal substrate.

Further, the first receiving groove extends from one edge of the thermally conductive metal substrate to an opposing edge.

Further, the second receiving groove is extended from one side of the thermally conductive metal substrate to an opposing side.

Further, the supporting substrate is made of aluminum nitride (AlN) materials.

Further, the vertical heat-dissipating block is made of aluminum nitride (AlN) materials.

Further, the thermally conductive metal substrate is made of copper (Cu) materials.

Further, a metal solder layer provided between the supporting substrate and the laser diode so as to fix the laser diode to the supporting substrate.

Further, the metal solder layer is made of gold-tin alloy (AuSn) materials.

As above, comparing to the convention heat-dissipating substrates, the present invention has the following advantages:

1. The assembly of semiconductor and highly thermally conductive heat-dissipating substrates of the present invention has the vertical thermal expansion effectively controlled so that the laser diode supported on the heat-dissipating substrates will not be shifted by thermal expansion of the substrates. This also prevents a change in position of the optical path of the assembly and reduction in optical coupling efficiency.

2. Most of the assembly of semiconductor and highly thermally conductive heat-dissipating substrates of the present invention is made of metal so that the overall thermal conduction efficiency of the heat-dissipating substrates is greatly increased.

### BRIEF DESCRIPTION OF THE SEVERAL VIEWS OF THE DRAWINGS

FIG. 1 is the perspective view of the first embodiment of the present invention.

FIG. 2 is the exploded perspective view of the first embodiment of the present invention.

FIG. 3 is the sectional view of the first embodiment of the present invention.

FIG. 4 is the perspective view of the second embodiment of the present invention.

FIG. 5 is the exploded perspective view of the second embodiment of the present invention.

FIG. 6 is the sectional view of the second embodiment of the present invention.

### DETAILED DESCRIPTION OF THE INVENTION

The details and technical solution of the present invention are hereunder described with reference to accompanying drawings. For illustrative sake, the accompanying drawings are not drawn to scale. The accompanying drawings and the scale thereof are not restrictive of the present invention.

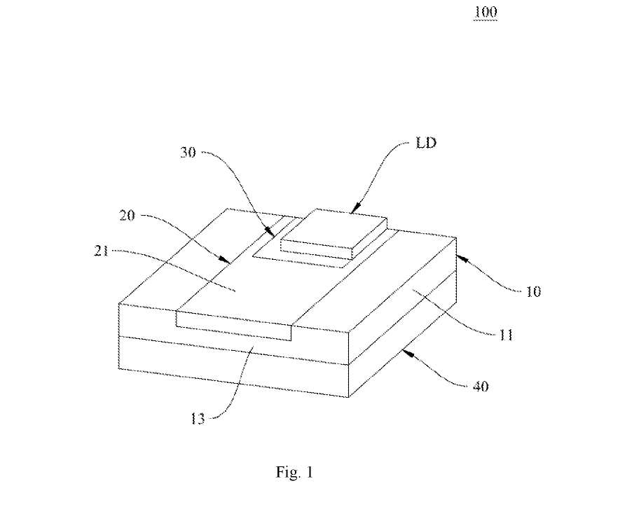

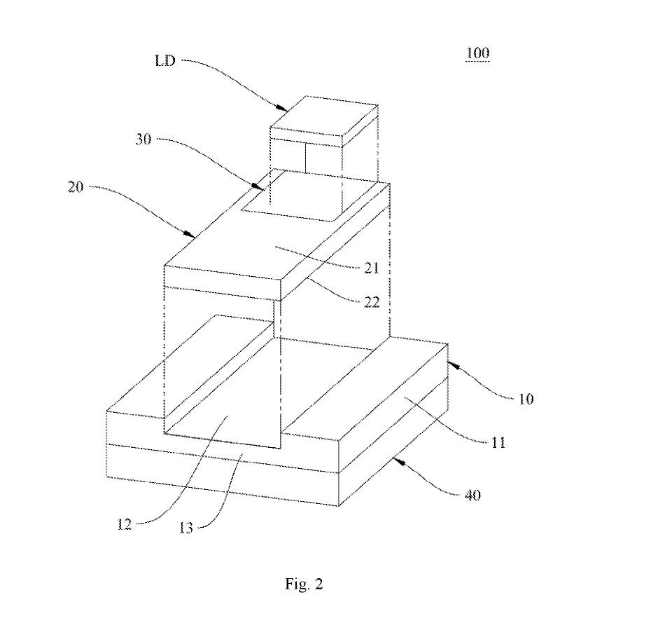

To begin with, please refer to FIG. 1 and FIG. 2 for an assembled perspective view and an exploded perspective view of the first embodiment of the present invention respectively.

In this embodiment, the assembly 100 of semiconductor and highly thermally conductive heat-dissipating substrates includes a thermally conductive metal substrate 10, a supporting substrate 20, and a vertical heat-dissipating block 40. The thermally conductive metal substrate 10 comprises a substrate body 11, a receiving groove 12 in the substrate body 11, and a thin-layer portion 13 at a bottom side of the receiving groove 12. Preferably, the receiving groove 12 extends from one edge of the thermally conductive metal substrate 10 to the opposite edge. Preferably, the receiving groove 12 may alternatively be provided in a middle, front, or rear portion of the thermally conductive metal substrate 10; the present invention imposes no limitation in this regard.

More specifically, the thermally conductive metal substrate 10 is made of a material of high thermal conductivity such as copper (Cu), copper-tungsten (CuW), a copper alloy, copper-molybdenum (CuMo), aluminum (Al), an aluminum alloy, a diamond/copper composite, or heat-dissipating ceramic. Preferably, the thermally conductive metal substrate 10 is made of copper (Cu) materials, which has a desirable high thermal conductivity. In addition, a thickness of the thin-layer portion 13 is controlled during the manufacturing process to be not greater than half a thickness of the thermally conductive metal substrate 10 so that, when the thin-layer portion 13 absorbs the heat conducted from the supporting substrate 20, the amount of vertical expansion of the thin-layer portion 13 is effectively controlled within an acceptable tolerance.

The supporting substrate 20 is provided in the receiving groove 12 and has a lower coefficient of thermal expansion than the thermally conductive metal substrate 10. The two vertically opposite sides of the supporting substrate 20 respectively form a carrying surface 21 for carrying a laser diode LD and a heat-dissipating surface 22 in contact with the thin-layer portion 13 at the bottom side of the receiving groove 12. The heat generated by the laser diode LD is absorbed by the carrying surface 21, diffuses to the heat-dissipating surface 22, and is conducted through the heat-dissipating surface 22 to the thin-layer portion 13 at the bottom side of the receiving groove 12.

The supporting substrate 20 may be made of aluminum nitride (AlN), silicon carbide (SiC), aluminum oxide (Al₂O₃), or a compound or composite material including any of the foregoing; the present invention has no limitation in this regard. Preferably, the supporting substrate 20 is made of aluminum nitride (AlN) materials because aluminum nitride has a low coefficient of thermal expansion (CTE) as well as high thermal conductivity and is therefore not prone to expansion or contraction in response to changes in temperature. When made of aluminum nitride, the supporting substrate 20 does not tend to expand or contract as a result of temperature variations, and this helps keep the laser diode LD from shifting in position.

The vertical heat-dissipating block 40 is provided on a side of the thermally conductive metal substrate 10 that faces away the receiving groove 12, and has a lower coefficient of thermal expansion than the thermally conductive metal substrate 10 such that the entire structure has a relatively low coefficient of thermal expansion. The fact that the vertical heat-dissipating block 40 is not readily susceptible to thermal expansion, or deformation, when subjected to heat also contributes to proper thermal conduction through the entire assembly. The vertical heat-dissipating block 40 is configured to absorb the heat conducted downward from the thin-layer portion 13 and guide the absorbed heat to a housing either directly or indirectly.

The vertical heat-dissipating block 40 may be made of aluminum nitride (AlN), silicon carbide (SiC), aluminum oxide (Al₂O₃), or a compound or composite material including any of the foregoing; the present invention has no limitation in this regard. Preferably, the vertical heat-dissipating block 40 is made of aluminum nitride (AlN) materials because aluminum nitride has a low coefficient of thermal expansion as well as high thermal conductivity and is therefore not prone to expansion or contraction in response to changes in temperature, meaning the vertical heat-dissipating block 40 is less likely to deform as a result of temperature variations.

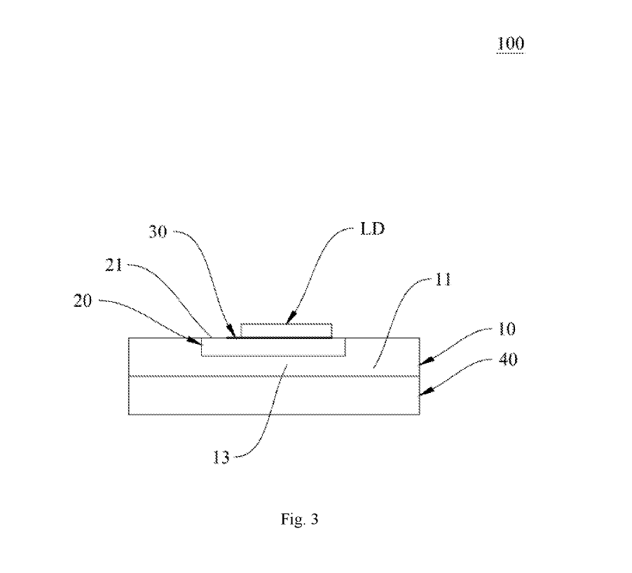

Please also refer to FIG. 3 for a sectional view of the first embodiment of the present invention.

Specifically, the laser diode LD is an edge-emitting laser diode, is provided on the supporting substrate 20, and is fixed to the supporting substrate 20 via a metal solder layer 30, wherein the metal solder layer 30 is preferably a highly thermally conductive material such as gold (Au), tin (Sn), a gold-tin alloy, other metal, or an alloy or composite material including any of the foregoing; the present invention has no limitation in this regard.

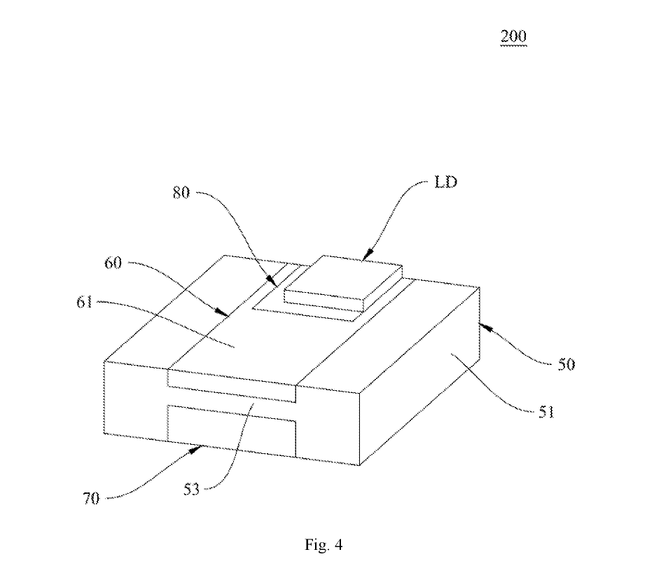

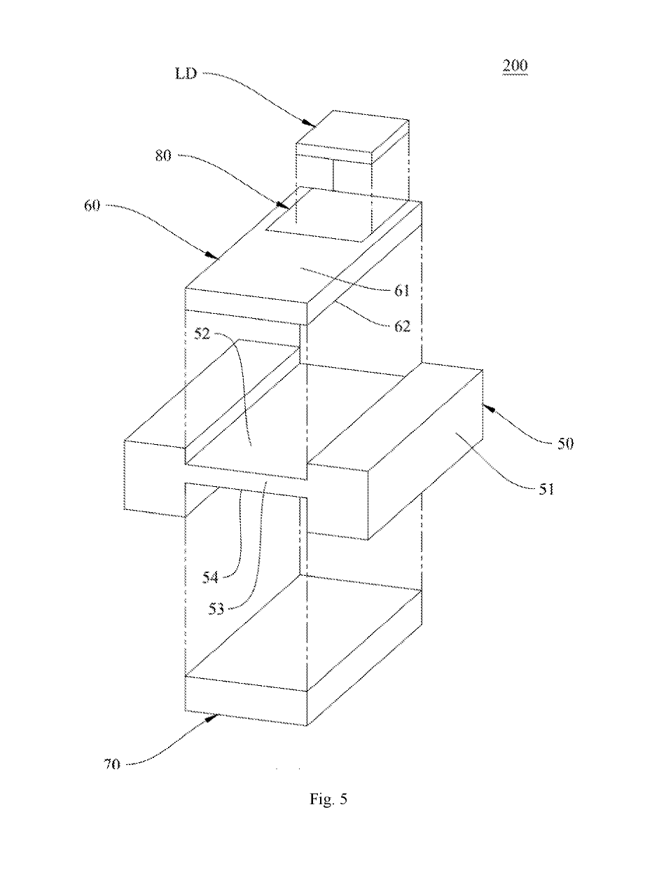

FIG. 4 and FIG. 5 show an assembled perspective view and an exploded perspective view of the second embodiment of the present invention respectively.

This embodiment provides the assembly 200 of semiconductor and highly thermally conductive heat-dissipating substrates, as shown in FIG. 4 and FIG. 5. The assembly of semiconductor and highly thermally conductive heat-dissipating substrates 200 includes a thermally conductive metal substrate 50, a supporting substrate 60, and a vertical heat-dissipating block 70. The thermally conductive metal substrate 50 comprises a substrate body 51, a first receiving groove 52 in the substrate body 51, a second receiving groove 54 on a side of the substrate body 51 that faces away from the first receiving groove, and a thin-layer portion 53 between the first receiving groove 52 and the second receiving groove 54. Preferably, the first receiving groove 52 extends from one edge of the thermally conductive metal substrate 50 to the opposite edge, and the second receiving groove 54, which is provided on the side of the substrate body 51 that faces away from the first receiving groove 52, also extends from one edge of the thermally conductive metal substrate 50 to the opposite edge. The first receiving groove 52 and the second receiving groove 54 may alternatively be provided in a middle, front, or rear portion of the thermally conductive metal substrate 50; the present invention imposes no limitation in this regard.

Specifically, the thermally conductive metal substrate 50 is made of a material of high thermal conductivity such as copper (Cu), copper-tungsten (CuW), a copper alloy, copper-molybdenum (CuMo), aluminum (Al), an aluminum alloy, a diamond/copper composite, or heat-dissipating ceramic. Preferably, the thermally conductive metal substrate 50 is made of copper (Cu) materials, which has high thermal conductivity. In addition, a thickness of the thin-layer portion 53 is controlled during the manufacturing process to be not greater than half a thickness of the thermally conductive metal substrate 50 so that, when the thin-layer portion 53 absorbs the heat conducted from the supporting substrate 60, the amount of vertical expansion of the thin-layer portion 53 is effectively controlled within an acceptable tolerance.

The supporting substrate 60 is provided in the first receiving groove 52 and has a lower coefficient of thermal expansion than the thermally conductive metal substrate 50. The two vertically opposite sides of the supporting substrate 60 respectively form a carrying surface 61 for carrying a laser diode LD and a heat-dissipating surface 62 in contact with the thin-layer portion 53 at the bottom side of the first receiving groove 52. The heat generated by the laser diode LD is absorbed by the carrying surface 61, diffuses to the heat-dissipating surface 62, and is conducted through the heat-dissipating surface 62 to the thin-layer portion 53 at the bottom side of the first receiving groove 52.

The supporting substrate 60 may be made of aluminum nitride (AlN), silicon carbide (SiC), aluminum oxide (Al₂O₃), or a compound or composite material including any of the foregoing; the present invention has no limitation in this regard. Preferably, the supporting substrate 60 may be made of aluminum nitride (AlN) materials, which has a low coefficient of thermal expansion as well as high thermal conductivity and is therefore not prone to expansion or contraction in response to temperature variations. Using a supporting substrate 60 made of aluminum nitride helps prevent the laser diode LD, and hence the optical path of the assembly, from shifting due to changes in temperature and thereby avoids reduction in optical coupling efficiency.

The vertical heat-dissipating block 70 is provided in the second receiving groove 54 and has a lower coefficient of thermal expansion than the thermally conductive metal substrate 50. The fact that the vertical heat-dissipating block 70 is not readily susceptible to thermal expansion, or deformation, when subjected to heat also contributes to proper thermal conduction through the entire assembly. The vertical heat-dissipating block 70 is configured to absorb the heat conducted downward from the thin-layer portion 53 and guide the absorbed heat to a housing either directly or indirectly.

The vertical heat-dissipating block 70 may be made of aluminum nitride (AlN), silicon carbide (SiC), aluminum oxide (Al₂O₃), or a compound or composite material including any of the foregoing; the present invention has no limitation in this regard. Preferably, the vertical heat-dissipating block 70 is made of aluminum nitride (AlN) materials because aluminum nitride has a low coefficient of thermal expansion as well as high thermal conductivity and is therefore not prone to expansion or contraction in response to changes in temperature, meaning the vertical heat-dissipating block 70 is less likely to deform as a result of temperature variations.

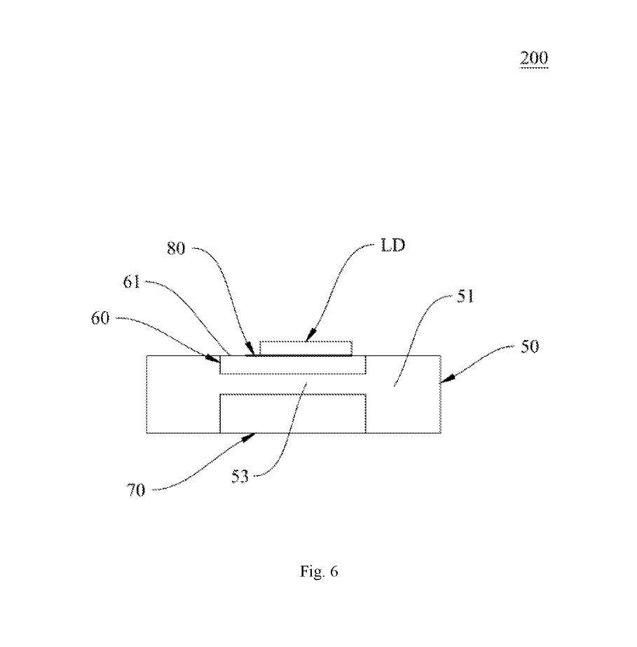

Please also refer to FIG. 6 for a sectional view of the second embodiment of the present invention.

Specifically, the laser diode LD is provided on the supporting substrate 60 and is fixed to the supporting substrate 60 through a metal solder layer 80, wherein the metal solder layer 80 is made of a high thermal conductivity material such as gold (Au), tin (Sn), a gold-tin alloy, other metal, or an alloy or composite material including any of the foregoing; the present invention has no limitation in this regard.

As above, the assembly of semiconductor and highly thermally conductive heat-dissipating substrates of the present invention has the vertical thermal expansion effectively controlled so that the laser diode supported on the heat-dissipating substrates will not be shifted by thermal expansion of the substrates. This also prevents a change in position of the optical path of the assembly and reduction in optical coupling efficiency. In addition, the assembly of semiconductor and highly thermally conductive heat-dissipating substrates of the present invention has the most of the assembly made of metal so that the overall thermal conduction efficiency of the heat-dissipating substrates is greatly increased.

While the present invention has been described in connection with certain exemplary embodiments, it is to be understood that the invention is not limited to the disclosed embodiments, but, on the contrary, intended to cover various modifications and equivalent arrangements included within the spirit and scope of the appended claims and equivalents thereof.

What is claimed is:

1. An assembly of semiconductor and highly thermally conductive heat-dissipating substrates, including:
a thermally conductive metal substrate, comprising a substrate body, a receiving groove in the substrate body, and a thin-layer portion at an bottom side of the receiving groove;
a supporting substrate, provided in the receiving groove, having a lower coefficient of thermal expansion than the thermally conductive metal substrate, and having two vertically opposite sides that respectively form a carrying surface for carrying a laser diode and a heat-dissipating surface in contact with the thin-layer portion at the bottom side of the receiving groove; and
a vertical heat-dissipating block, provided on a side of the thermally conductive metal substrate that faces away the receiving groove, and having a lower coefficient of thermal expansion than the thermally conductive metal substrate so as to absorb heat conducted downward from the thin-layer portion.

2. The assembly of claim 1, wherein a thickness of the thin-layer portion is not greater than half of that of the thermally conductive metal substrate.

3. The assembly of claim 1, wherein the receiving groove extends from one edge of the thermally conductive metal substrate to an opposing edge.

4. The assembly of claim 1, wherein the supporting substrate is made of aluminum nitride (AlN) materials.

5. The assembly of claim 1, wherein the thermally conductive metal substrate is made of copper (Cu) materials.

6. The assembly of claim 1, wherein the vertical heat-dissipating block is made of aluminum nitride (AlN) materials.

7. The assembly of claim 1, further comprising a metal solder layer provided between the supporting substrate and the laser diode so as to fix the laser diode to the supporting substrate.

8. The assembly of claim 7, wherein the metal solder layer is made of gold-tin alloy materials.

9. An assembly of semiconductor and highly thermally conductive heat-dissipating substrates, including:
a thermally conductive metal substrate, comprising a substrate body, a first receiving groove in the substrate body, a second receiving groove on a side of the substrate body that faces away from the first receiving groove, and a thin-layer portion between the first receiving groove and the second receiving groove;
a supporting substrate, provided in the first receiving groove, having a lower coefficient of thermal expansion than the thermally conductive metal substrate, and having two vertically opposite sides that respectively form a carrying surface for carrying a laser diode and a heat-dissipating surface in contact with the thin-layer portion at an bottom side of the first receiving groove; and
a vertical heat-dissipating block, provided in the second receiving groove, and having a lower coefficient of thermal expansion than the thermally conductive metal substrate so as to absorb heat conducted downward from the thin-layer portion.

10. The assembly of claim 9, a thickness of the thin-layer portion is not greater than half of that of the thermally conductive metal substrate.

11. The assembly of claim 9, wherein the first receiving groove extends from one edge of the thermally conductive metal substrate to an opposing edge.

12. The assembly of claim 9, wherein the second receiving groove extends from one side of the thermally conductive metal substrate to an opposing side.

13. The assembly of claim 9, wherein the supporting substrate is made of aluminum nitride (AlN) materials.

14. The assembly of claim 9, wherein the vertical heat-dissipating block is made of aluminum nitride (AlN) materials.

15. The assembly of claim 9, wherein the thermally conductive metal substrate is made of copper (Cu) materials.

16. The assembly of claim 9, further comprising a metal solder layer provided between the supporting substrate and the laser diode so as to fix the laser diode to the supporting substrate.

17. The assembly of claim 16, wherein the metal solder layer is made of gold-tin alloy materials.
